(19) United States
(12) Patent Application Publication
(10) Pub. No.: US 2016/0174398 A1
(43) Pub. Date: Jun. 16, 2016

(54) ELECTRONIC APPARATUS

(71) Applicant: KABUSHIKI KAISHA TOSHIBA, Tokyo (JP)

(72) Inventor: Shunsuke IDO, Tokyo (JP)

(73) Assignee: KABUSHIKI KAISHA TOSHIBA, Tokyo (JP)

(21) Appl. No.: 14/846,470

(22) Filed: Sep. 4, 2015

Related U.S. Application Data
(60) Provisional application No. 62/092,683, filed on Dec. 16, 2014.

(51) Int. Cl. H05K 5/02; H05K 5/00

(52) U.S. Cl. CPC H05K 5/0217; H05K 5/0017

(57) ABSTRACT

According to one embodiment, an electronic apparatus having a touchpanel function in one embodiment has a support portion supporting a front panel under circumstances where a screen of a display device and a front panel are bonded together without any intervening spaces. The support portion has holders for holding corners of the display device.

### CROSS-REFERENCE TO RELATED APPLICATIONS

This application claims the benefit of U.S. Provisional Application No. 62/092,683, filed Dec. 16, 2014, the entire contents of which are incorporated herein by reference.

### FIELD

Embodiments described herein relate generally to an electronic apparatus.

### BACKGROUND

Reduction in thickness of an electronic apparatus having a touchpanel function is promoted by bonding together a screen of a display device and one of a touchpanel or a protective panel arranged on the screen without any intervening spaces.

A touchpanel or a protective panel becomes thinner as an electronic apparatus becomes thinner. Therefore, if pressure exerted by the finger of a user on a touchpanel or a protective panel while the user is using an electronic apparatus, the touchpanel or the protective panel may separate from a display device depending on the degree of pressure.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view of an electronic apparatus in one embodiment;

FIG. 2 is en exemplary plan view of the electronic apparatus of FIG. 1;

FIG. 3 is an exemplary sectional view taken along a break line F3-F3 of FIG. 2;

FIG. 4 is an exemplary sectional view of the rear of the electronic apparatus taken along a break line F4-F4 of FIG. 3 and illustrating holders holding corners of the display device;

FIG. 5 is an exemplary plan view of the rear of the electronic apparatus illustrating that each of the holders is provided with a beam;

FIG. 6 is an exemplary perspective view of one of the holders of FIG. 5 as obliquely viewed from above;

FIG. 7 is an exemplary perspective view of one of the holders as obliquely viewed from above illustrating that parallel extending beams are provided;

FIG. 8 is an exemplary perspective view of one of the holders as obliquely viewed from above illustrating that radially extending beams are provided;

FIG. 9 is an exemplary plan view of one of the holders in a modified example as viewed from just below;

FIG. 10 is an exemplary perspective view of the holder of FIG. 9 as obliquely viewed from above;

FIG. 11 is an exemplary plan view illustrating a holder in a modified example as viewed from just below;

FIG. 12 is an exemplary perspective view illustrating the holder of FIG. 11 as obliquely viewed from above;

FIG. 13 is an exemplary plan view illustrating a holder in a modified example as viewed from just below; and

FIG. 14 is an exemplary perspective view illustrating the holder of FIG. 13 as obliquely viewed from above.

### DETAILED DESCRIPTION

Various embodiments will be described hereinafter with reference to the accompanying drawings. In general, according to one embodiment, an electronic apparatus in one embodiment has a touchpanel function. The electronic apparatus generally has a support portion supporting a front panel under circumstances where a screen of a display device and a front panel are bonded together without any intervening spaces. The support portion has holders for holding corners of the display device.

Now, an electronic apparatus in one embodiment will be explained below with reference to the drawings.

An electronic apparatus in one embodiment may be a computer equipped with a monitor having a touchpanel function. A notebook computer or a tablet computer, for instance, may represent the electronic apparatus of the embodiment. A tablet computer (hereinafter referred to as a “tablet device”) will be explained below as an example of the electronic apparatus of the embodiment.

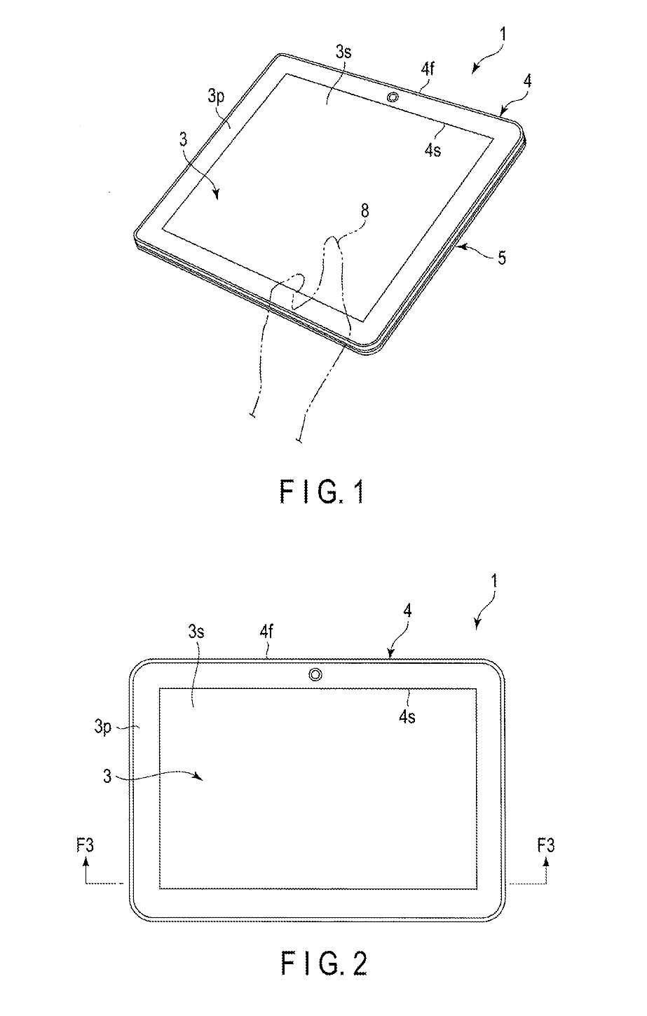

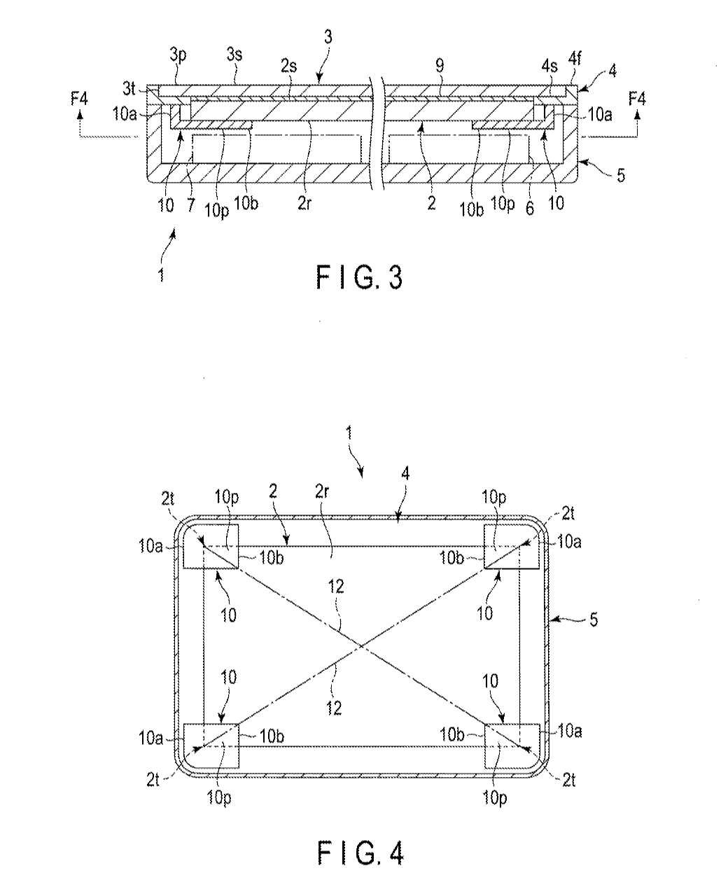

As illustrated in FIG. 1 to FIG. 4, an electronic apparatus (tablet device) 1 comprises a display device 2 having a screen 2s, a front panel 3 (namely, a touchpanel 3) arranged to cover the screen 2s, and a case 5 having a support portion 4 supporting the front panel 3 (the touchpanel 3). The case 5 accommodates a control board 6, a battery 7, etc., for operating the tablet device 1.

It should be noted that there may be two variations of an envisioned tablet device 1 in the present embodiment. A device of a first variation, for instance, comprises a front panel 3 provided with a touch sensor and functioning as a touchpanel, whereas a device of a second variation comprises a display device 2 integrated with a touchpanel and uses a front panel 3 as a protective panel (for instance, a cover glass) protecting the screen 2s of the display device 2. A tablet device 1 of the first variation will be mainly explained below as an example of the embodiment. However, what will be explained below may also be applicable to a tablet device 1 of the second variation. It should be noted that a front panel 3 in any variation is made of a material allowing light to pass through.

A liquid crystal display (LCD) or an organic electroluminescent display, for instance, may be used as the display device 2. The display device 2 is electrically connected through a non-illustrated flexible circuit to the aforementioned control board 6. This configuration makes it possible to display textual or graphical data on the screen 2s of the display device 2, for instance. It should be noted that a monitor designed to have a structure in which the display device 2 is identical to the screen 2s in outline dimension is illustrated in the drawings by way of example.

The front panel (touchpanel) 3 is a device which allows a user to operate a computer by directly touching with a finger 8 (FIG. 1) an icon or a button displayed on the screen 2s of the display device 2. The front panel (touchpanel) 3 is electrically connected through a non-illustrated flexible circuit to the aforementioned control board 6, for instance. This configuration makes it possible to determine a contact position based on the change in voltage or capacitance which occurs whenever the user's finger 8 touches the screen 2s.

In the present embodiment, the screen 2s of the display device 2 and the front panel (touchpanel) 3 are bonded together in advance without any intervening spaces and are supported together by the support portion 4 under the bonded state. The support portion 4 and the case 5 may be simultaneously formed as a single body in a production process of the case 5 or, alternatively, the support portion 4 and the case 5 may be separately formed and then be combined together.

The screen 2s of the display device 2 and the front panel (touchpanel) 3 are bonded together by an adhesive agent 9, for instance, without any intervening spaces. An optically clear adhesive (OCA) or an optically clear resin (OCR), for instance, may be used as the adhesive agent 9.

The front panel (touchpanel) 3 is larger in area than the screen 2s of the display device 2. Therefore, when the screen 2s of the display device 2 and the front panel (touchpanel) 3 are bonded together without any intervening spaces, the perimeter 3p of the front panel (touchpanel) 3 protrudes from the display device 2 the screen 2s) and becomes an outwardly extending region. The front panel (touchpanel) 3 is uniform in thickness.

The aforementioned support portion 4 continuously extends along the perimeter of the front panel (touchpanel) 3 so as to surround the display device 2. That is, the support portion 4 is a rectangular hollow frame having an empty space within it. The empty space inside the support portion 4 is slightly larger in area than the display device 2 (the screen 2s).

The support portion 4 has a contour conforming to the contour of the extending portion 3p or the perimeter 3p of the front panel (touchpanel) 3. The support portion 4 has a flange 4f located at and projecting from the outside of the support portion 4. The flange 4f continuously extends along the contour of the support portion 4. The flange 4f has a height that is equal in dimension to the thickness of the front panel (touchpanel) 3 supported by the support portion 4.

The display device 2 and the front panel (touchpanel) 3, which are bonded together without any intervening spaces, are installed in the case 5. For instance, the control board 6 and the battery 7 are firstly installed in the case 5 to operate the tablet device 1. Then, the display device 2 and the front panel (touchpanel) 3, which are bonded together without any intervening spaces, are supported by the support portion 4. At this moment, the display device 2 is fit In the central region (namely, the hollow region) of the support portion 4.

In this way, the perimeter (extending portion) 3p of the front panel (touchpanel) 3 alone will be supported by the frame shaped support portion 4. Specifically, the support portion 4 has a supporting surface 4s extending inward from the flange 4f and continuously running along the flange 4f. By means of such a construction, the perimeter (extending portion) 3p of the front panel (touchpanel) 3 is supported by the supporting surface 4s.

At the same time, the outer edge 3t of the front panel (touchpanel) 3 is positioned by the flange 4f of the support portion 4. The thickness of the front panel (touchpanel) 3 is equal to the height of the flange 4f. The front panel (touchpanel) 3 therefore will be flush with the support portion 4. As a result, the input surface of the tablet device 1, including the surface 3s of the front panel (touchpanel) 3, will be wholly flat and completely free from any differences or irregularities in level.

In this embodiment, the support portion 4 has holders 10 for holding the respective corners 2t of the display device 2. The holders 10 support the respective corners 26 of the display device 2 from the rear surface 2r opposite to the screen 2s. Each of the holders 10 has a base and 10a fixed to the support portion 4 and a free end 10b lust under the rear surface 2r of the display device 2.

It should be noted that the corners 2t define the outline of the display device 2. For instance, a triangular display device has three corners. A rectangular display device has four corners. A pentagonal display device has five corners. A rectangular display device 2 having four corners 2t is illustrated in the drawings as an example.

Either of the following two methods may be used to fix the base end 10a of each of the holders 10 to the support portion 4. The support portion 4 and the holders 10 may be simultaneously formed as single body in a production process of the support portion 4 or, alternatively, the support portion 4 and the holders 10 may be separately formed and the be combined together.

There are two ways to combine the base end 10a or each of the holders 10 with the support portion 4 in the latter method. For instance, the base end 10a of each of the holders 10 may be bonded to the support portion 4 or, alternatively, the base end 10a of each of the holders 10 may be welded into the support portion 4.

Each of the holders 10 has a holding portion 10p defining the free end 10b and holding the rear surface 2r of the display device 2. The holding portion 10p has a shape allowing the holding portion 10p to be in contact with the rear surface 2r of the display device 2. What is illustrated in the drawings as an exemplified shape of each holding portion 10p is a rectangle. Each rectangular holding portion 10p spreads on the corresponding one of the corners of the rear surface 2r of the display device 2. This construction makes it possible for the holding portions 10p to hold the respective corners 2t of the display device 2 from the rear surface 2r of the display device 2 under the condition in which the display device 2 is supported by the support portion 4 along with the front panel (touchpanel) 3.

The application of pressure from the user's finger 8 to the surface 3s of the front panel (touchpanel) 3 (or the input surface of the tablet device 1) while the tablet device 1 is being used may cause the front panel (touchpanel) 3 supported by the support portion 4 to warp. It should be noted that the front panel (touchpanel) 3 may peel of the display device 2 depending on the degree of (or extent of the) warpage. The corners 2t of the display device 2 are the most easily peeled off.

The provision of the holders 10 to the respective corners of the support portion 4 to hold the corresponding corners 2t of the display device 2 makes it possible to prevent the front panel (touchpanel) 3 from warping or to make the degree of (or extent of the) warpage of the front panel (touchpanel) 3 as small as possible even if a pressure is applied from the user's finger 8 to the input surface of the tablet device 1. As a result, the front panel (touchpanel) 3 will be prevented from peeling off the display device 2 or separation of the front panel (touchpanel) 3 from the display device 2 will be eliminated.

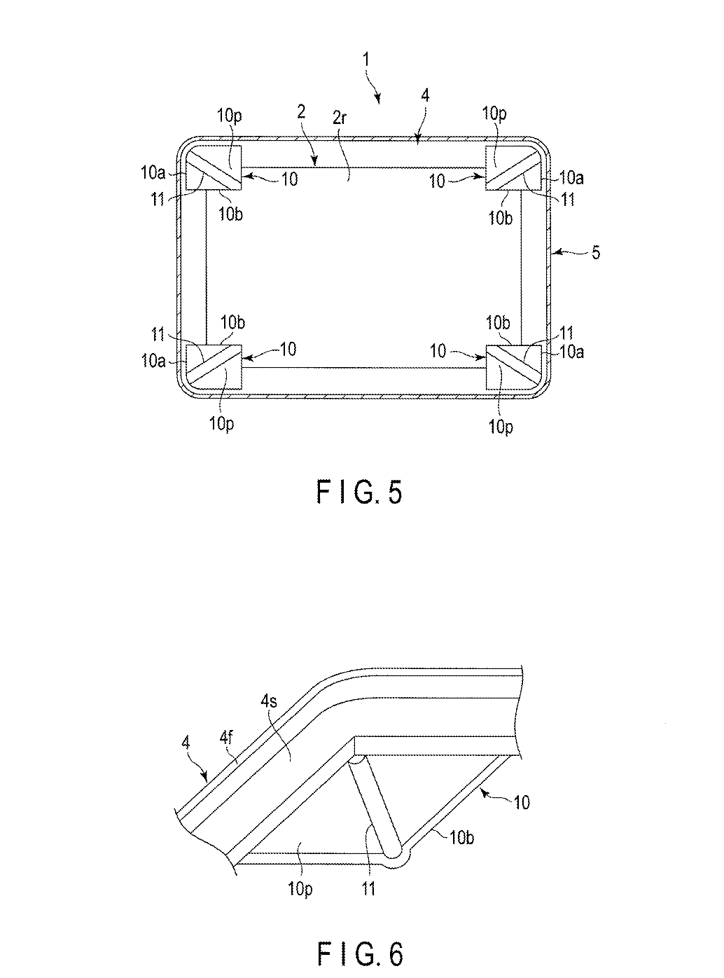

As illustrated in FIG. 5 and FIG. 6, a beam 11 may be provided on each of the holding portions 10p in order to maintain prescribed rigidity for each of the holding portions 10p. Either of the following two methods may be used to form the beam 11. The holding portion 10p and the beam 11 may be simultaneously formed as a single body in a production process of the holding portion 10p or, alternatively, the holding portion 10p and the beam 11 may be separately formed and then be combined together. What is illustrated in the drawings as an example is a case of forming the beam 11 simultaneously with the holding portion 10p. The beam 11 is an indentation in the holding portion 10p.

The beam 11 having the above construction extends across the holding portion 10p. The beam 11 extends toward the center of the display device 2 or the periphery of the center. What is illustrated in the drawings as an example is a beam 11 extending along a diagonal 12 joining two corners 2t (FIG. 4).

The depth of the indentation forming the beam 11 may be determined in such a manner that the beam 11 forms the so-called truss structure, for instance. Let us suppose that a beam has the shape of a prism or a semi-cylinder. The provision of such a beam on each of the holding portions 10p makes it possible to maintain prescribed rigidity for each of the holding portions 10p. As a result, sufficient strength to withstand the pressure applied from a user's finger 8 can be secured for the holding portion 10p irrespective of shape and size of the holding portion 10p.

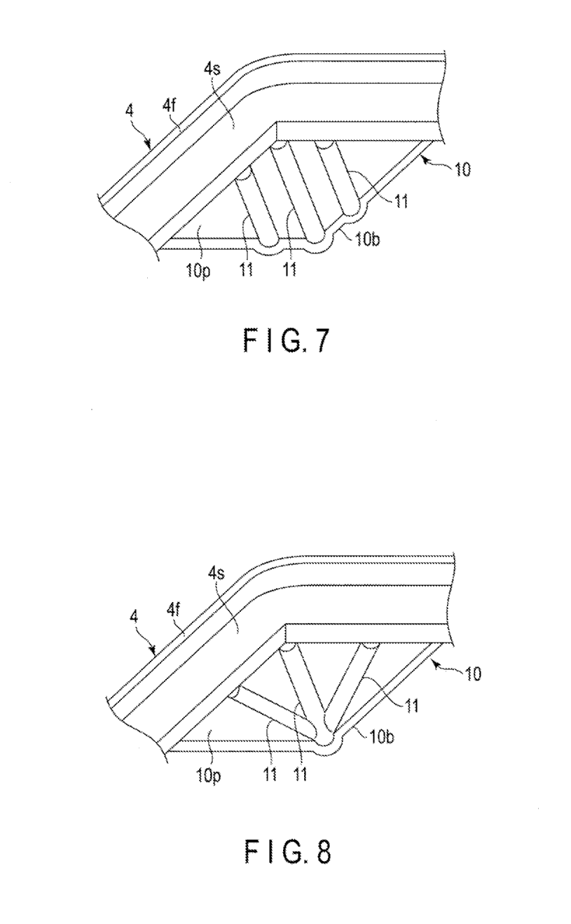

The number of beams 11 is not limited to one, but a plurality of beams 11 can be provided to each of the holding portions 10p. In the latter case, the beams 11 may extend parallel to one another (FIG. 7), or may extend radially to converge on one point (FIG. 8). The beams 11 illustrated in FIG. 8 are so constructed as to converge on a point where one of the beams 11 extending along a diagonal 12 terminates at the free end 10b of the holder 10 (holding portion 10p). Three beams 11 are illustrated in FIG. 8 as an example. However, the number of the beams 11 is not limited to three but two or more than three beams 11 may be provided to each of the holding portions 10p.

In the above embodiment, we assumed that a holder 10 has rectangular holding portions 10p. However, the shape of the holding portions 10p is not limited to a rectangle, but such modifications as described below will be included in the technical scope of the claimed invention.

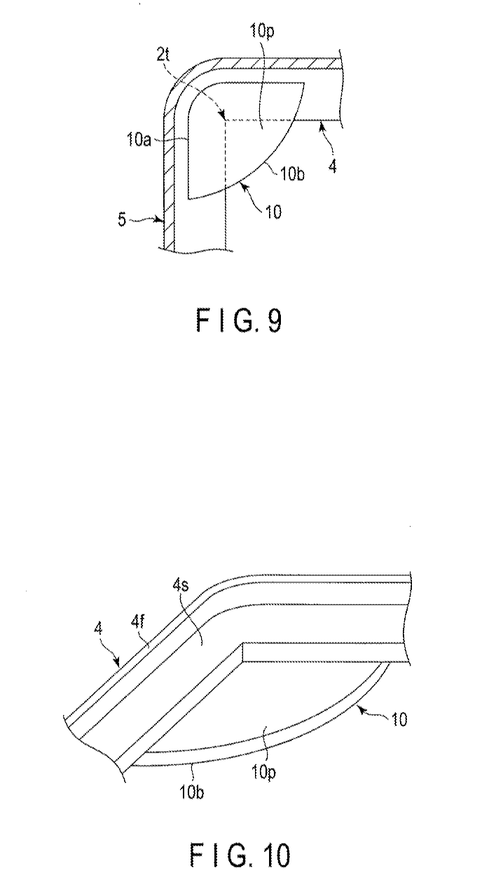

FIG. 9 and FIG. 10 individually illustrate a holder 10 having a quadrant holding portion 10p. The holder 10 (the holding portion 10p) has an arcuate free end 10b.

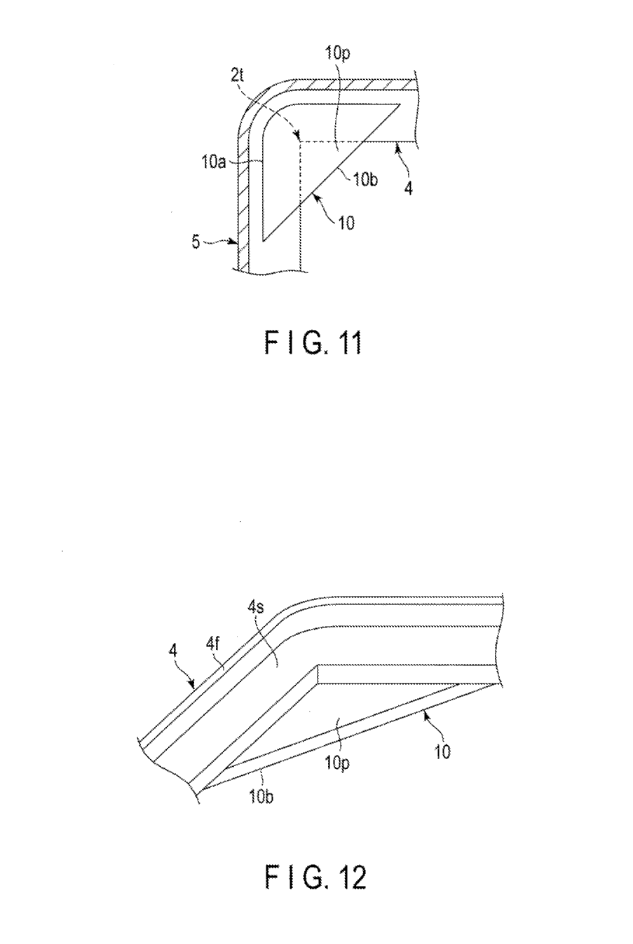

FIG. 11 and FIG. 12 individually illustrate a holder 10 having a triangular holding portion 10p. The holder 10 (the holding portion 10p) has a free end 10b which defines one side of the triangle.

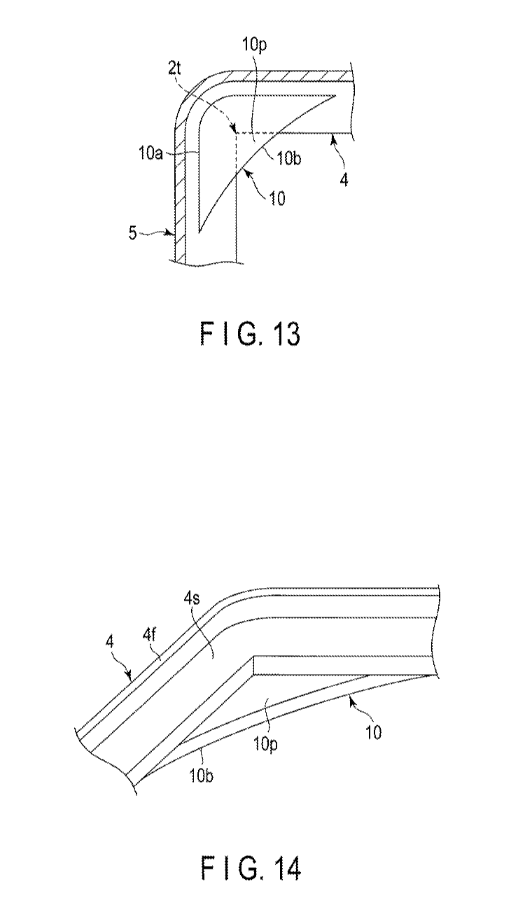

FIG. 13 and FIG. 14 individually illustrate a holder 10 having another triangular holding portion 10p. The holder 10 the holding portion 10p) has an incurved free end 10b.

Any of the above modified holders 10 (holding portions 10p) has the same function as the holder 10 (holding portion 10p) in the above embodiment. In addition, the provision of the beams 11 in the embodiment described above (FIG. 5 to FIG. 8) to any of the above modified holding portions 10p has the same function as the holder 10 in the above embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus having a touchpanel function comprising:
a display device including a screen having a perimeter and a plurality of corners at the perimeter of the screen;
a front panel spreading out on the screen; and
case having a support portion supporting the front panel under circumstances where the screen of the display device and the front panel are bonded together without any intervening spaces, wherein
the support portion has holders for holding the corners of the display device.

2. The electronic apparatus of claim 1, wherein the front panel has a perimeter, and the support portion continuously extends along the perimeter of the front panel so as to surround the display device and supports the perimeter of the front panel alone.

3. The electronic apparatus of claim 1, wherein the display device has a rear surface opposite to the screen, and the holders hold the corners of the display device from the rear surface opposite to the screen.

4. The electronic apparatus of claim 3, wherein each of the holders has a holding portion holding the rear surface of the display device, and each of the holding portions holds a corresponding one of the corners of the display device from the rear surface of the display device.

5. The electronic apparatus of claim 4, wherein each of the holding portions has at least one beam in order to maintain prescribed rigidity for each of the holding portions.

6. The electronic apparatus of claim 5, wherein
the display device has a center and a periphery of the center, and each of the beams extends across a corresponding one of the holding portions toward the center of the display device or the periphery of the center.

7. The electronic apparatus of claim 6, wherein each of the beams is an indentation in a corresponding one of the holding portions.

8. The electronic apparatus of claim 6, wherein the beams in any one of the holding portions extend parallel to one another.

9. The electronic apparatus of claim 6, wherein the beams in any one of the holding portions extend radially to converge on one point.
